(19) United States
(12) Patent Application Publication
(10) Pub. No.: US 2013/0077212 A1
(43) Pub. Date: Mar. 28, 2013

(54) ELECTRONIC APPARATUS

(71) Applicant: Yuji NAKAJIMA, Nishitama-gun (JP)

(72) Inventor: Yuji NAKAJIMA, Nishitama-gun (JP)

(73) Assignee: KABUSHIKI KAISHA TOSHIBA, Tokyo (JP)

(21) Appl. No.: 13/523,705

(22) Filed: Jun. 14, 2012

(30) Foreign Application Priority Data
Sep. 27, 2011 (JP) 2011-210808

(51) Int. Cl. H05K 5/02

(52) U.S. Cl. 361/679.01

(57) ABSTRACT

According to one embodiment, an electronic apparatus includes a first housing, a second housing, a first member, and a second member. The first member is supported by the first housing, the first member comprising a portion which is movable. The second member is supported by the first member in a first position in order that the second member comprises a portion between the second housing and the first housing in a first state where a second surface of the second housing faces the first housing. The second member is supported by the first member in a second position in order that the portion of the second member faces the second housing from a side opposite to the first housing in a second state where a first surface of the second housing faces the first housing.

### CROSS-REFERENCE TO RELATED APPLICATIONS

This application is based upon and claims the benefit of priority from prior Japanese Patent Application No. 2011-210808, filed Sep. 27, 2011; the entire contents of which are incorporated herein by reference.

### FIELD

Embodiments described herein relate generally to electronic apparatuses.

### BACKGROUND

A display device has been proposed in which the position of a display can be adjusted.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of an electronic apparatus according to a first embodiment;

FIG. 2 is an exemplary perspective view of a first state of the electronic apparatus illustrated in FIG. 1;

FIG. 3 is an exemplary cross-sectional view of the first state of the electronic apparatus illustrated in FIG. 1;

FIG. 4 is an exemplary cross-sectional view of the electronic apparatus illustrated in FIG. 2 taken along the line F4-F4;

FIG. 5 is an exemplary cross-sectional view of the electronic apparatus illustrated in FIG. 2 taken along the line F5-F5;

FIG. 6 is an exemplary perspective view of a second state of the electronic apparatus illustrated in FIG. 1;

FIG. 7 is an exemplary perspective view of the second state of the electronic apparatus illustrated in FIG. 1;

FIG. 8 is an exemplary perspective view of a third state of the electronic apparatus illustrated in FIG. 1;

FIG. 9 is an exemplary cross-sectional view of the third state of the electronic apparatus illustrated in FIG. 1;

FIG. 10 is an exemplary cross-sectional view of the electronic apparatus illustrated in FIG. 8 taken along the line F10-F10;

FIG. 11 is an exemplary cross-sectional view of the electronic apparatus illustrated in FIG. 8 taken along the line F11-F11;

FIG. 12 is an exemplary perspective view of a fourth state of the electronic apparatus illustrated in FIG. 1;

FIG. 13 is an exemplary perspective view of a first state of an electronic apparatus according to a second embodiment;

FIG. 14 is an exemplary perspective view of a second state of the electronic apparatus illustrated in FIG. 13;

FIG. 15 is an exemplary perspective view of the second state of the electronic apparatus illustrated in FIG. 13; and

FIG. 16 is an exemplary perspective view of a third state of the electronic apparatus illustrated in FIG. 13.

### DETAILED DESCRIPTION

Various embodiments will be described hereinafter with reference to the accompanying drawings.

In general, according to one embodiment, an electronic apparatus comprises a first housing, a second housing, a first member, and a second member. The second housing comprises a first surface and a second surface, the second surface opposite to the first surface. The first member is supported by the first housing, the first member comprising a portion movable between a first position and a second position, the second position further away from the first housing than the first position. The second member connects the first member and the second housing. The second member is supported by the first member in the first position in order that the second member comprises a portion between the second housing and the first housing in a first state where the second surface of the second housing faces the first housing. The second member is supported by the first member in the second position in order that the portion of the second member faces the second housing from a side opposite to the first housing in a second state where the first surface of the second housing faces the first housing.

In some drawings, a housing (i.e., unit) is hatched. The hatching does not indicate that the inside of the housing (i.e., unit) is dense, but the housing is hatched for convenience of explanation. Each housing (i.e., unit) includes an internal space in which components are accommodated.

### FIRST EMBODIMENT

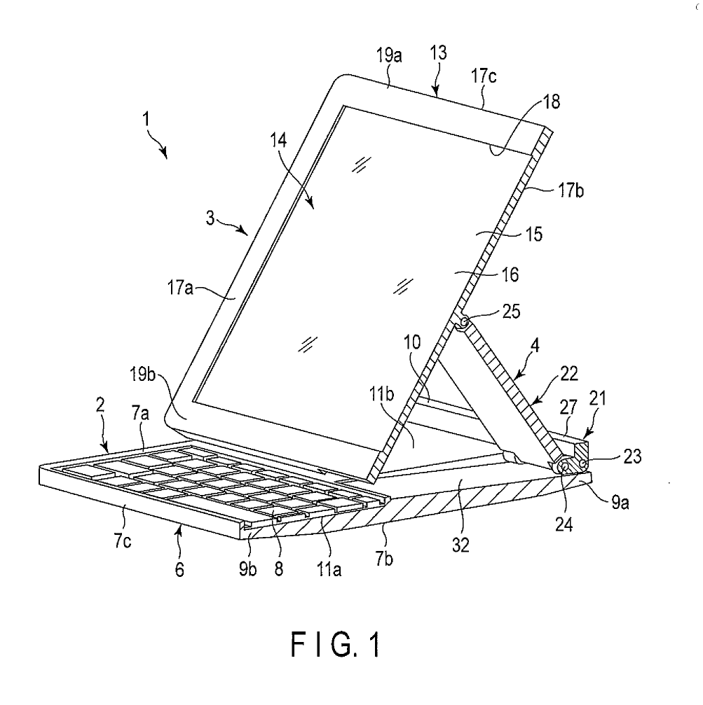

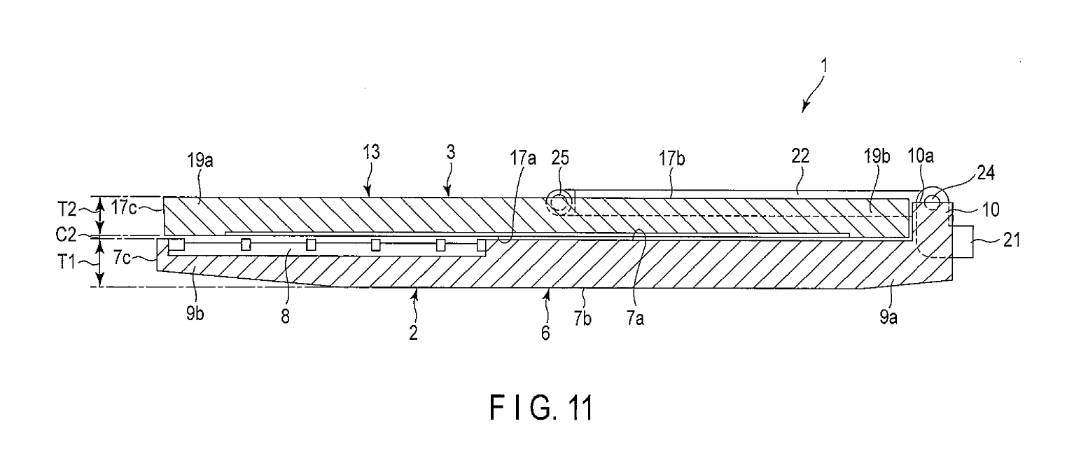

FIGS. 1 to 12 illustrate an electronic apparatus 1 according to a first embodiment. An example of the electronic apparatus 1 is a tablet portable computer (tablet PC). The electronic apparatus to which this embodiment can be applied is not limited to the example. This embodiment can be widely applied to various kinds of electronic apparatuses, such as notebook portable computers (notebook PCs), mobile telephones, smart phones, e-book readers, and game machines.

As illustrated in FIG. 1, the electronic apparatus 1 includes a first unit 2, a second unit 3, and a hinge portion 4. An example of the first unit 2 is a so-called main unit. The first unit 2 includes a first housing 6. The first housing 6 includes, for example, a circuit board and a battery.

The first housing 6 includes a first surface 7a (i.e., first wall), a second surface 7b (i.e., second wall), and a third surface 7c (i.e., third wall) and has a flat box shape. An example of the first surface 7a is an upper surface. An input portion 8 is provided on the first surface 7a. The input portion 8 is an example of a “first input portion” or a “first input receiving portion”. The input portion 8 is, for example, a keyboard.

The input portion 8 may be a display device provided with, for example, a touch sensor (i.e., touch panel) instead of the keyboard. In this case, the first surface 7a includes an opening through which a display screen provided with the touch sensor is exposed.

The second surface 7b is opposite to the first surface 7a. An example of the second surface 7b is a lower surface. The second surface 7b is opposite to the first surface 7a with a space therebetween and extends substantially in parallel to the first surface 7a. When the electronic apparatus 1 is placed on a desk (i.e., outer mounting surface), the second surface 7b faces the upper surface of the desk. A plurality of legs that come into contact with the upper surface of the desk and support the electronic apparatus 1 are provided on the second surface 7b.

An example of the third surface 7c is a circumferential surface (i.e., side surface). The third surface 7c extends in a direction crossing (for example, a direction substantially perpendicular to) the first surface 7a and the second surface 7b. The third surface 7c extends between the first surface 7a and the second surface 7b. That is, the third surface 7c connects the end of the first surface 7a and the end of the second surface 7b.

As illustrated in FIG. 1, the first housing 6 includes a first end 9a and a second end 9b. The first end 9a is, for example, a rear end and is connected to the hinge portion 4. The second end 9b is, for example, a front end and is opposite to the first end 9a.

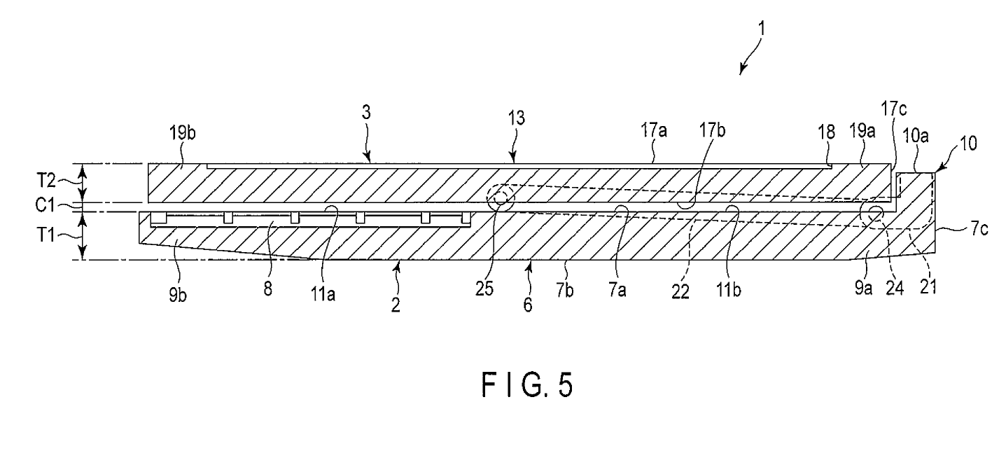

As illustrated in FIGS. 1 and 5, the first end 9a includes a projection 10. The projection 10 protrudes from the first surface 7a in the thickness direction of the first housing 6. That is, the projection 10 is higher than the first surface 7a. The upper end of the projection 10 includes a plane 10a. The plane 10a is closer to a first surface 17a of a second housing 13 than the first surface 7a of the first housing 6 in a first state (state illustrated in FIG. 5), which will be described below.

As illustrated in FIG. 1, the first surface 7a of the first housing 6 includes a first region 11a (i.e., first portion) and a second region 11b (i.e., second portion). The first region 11a is closer to the second end 9b than the center of the first surface 7a. The input portion 8 described above is provided in the first region 11a. The second region 11b is disposed between the first region 11a and the first end 9a.

An example of the second unit 3 is a so-called display unit (i.e., display portion). The second unit 3 includes the second housing 13. The second housing 13 includes a display device 14. A touch sensor 16 (i.e., touch panel) is provided on a display screen 15 of the display device 14. The second housing 13 may include a circuit board, instead of the first housing 6.

The second housing 13 includes a first surface 17a (i.e., first wall), a second surface 17b (i.e., second wall), and a third surface 17c (i.e., third wall) and has a flat box shape. An example of the first surface 17a is a display surface. The display screen 15 provided with the touch sensor 16 is exposed from the first surface 17a. That is, an opening portion 18 through which the display screen 15 is exposed is provided in the first surface 17a. The display screen 15 (i.e., the display device 14) is an example of a “second input portion” or a “second input receiving portion”.

An example of the second surface 17b is a rear surface. The second surface 17b is opposite to the first surface 17a. The second surface 17b has, for example, a planar shape (i.e., flat surface shape) and covers the rear surface of the display device 14. The third surface 17c is a circumferential surface (i.e., side surface). The third surface 17c extends in a direction crossing (for example, a direction substantially perpendicular to) the first surface 17a and the second surface 17b. The third surface 17c extends between the first surface 17a and the second surface 17b. That is, the third surface 17c connects the end of the first surface 17a and the end of the second surface 17b.

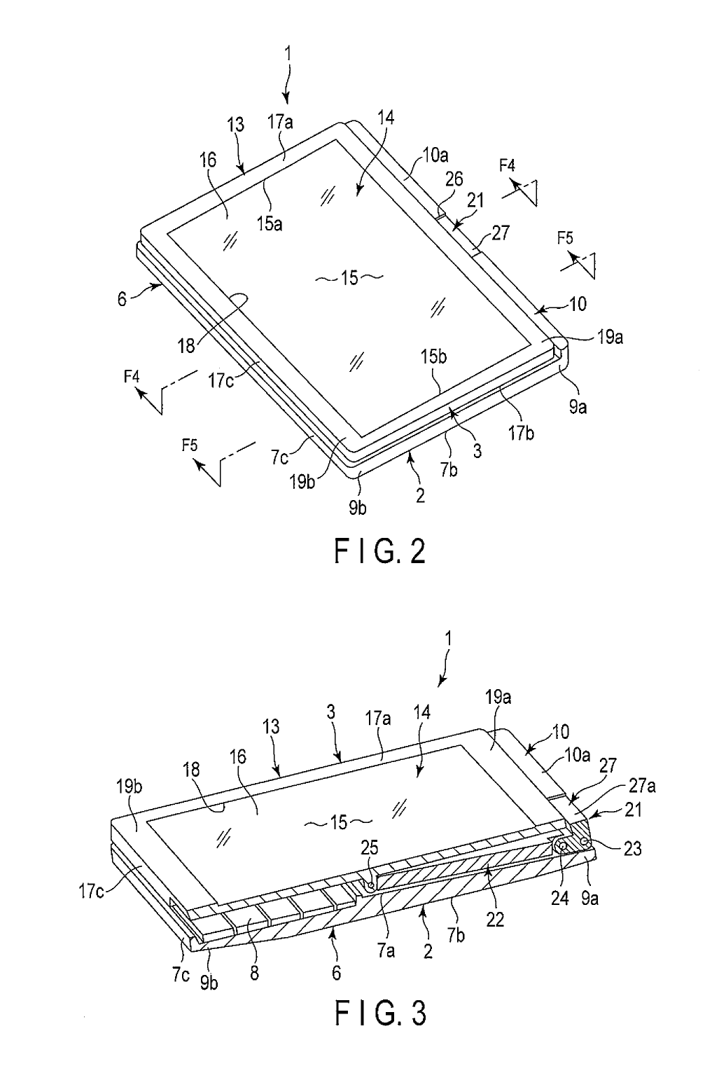

As illustrated in FIGS. 2 to 5, the second housing 13 includes a first end 19a and a second end 19b. The first end 19a faces the first end 9a of the first housing 6 in a state (i.e., first state) in which the display screen 15 is exposed upward. In the first state, a portion of the first end 19a of the second housing 13 faces a link 21 (i.e., first member), which will be described below. The second end 19b is opposite to the first end 19a. The second end 19b faces the second end 9b of the first housing 6 in the first state.

As illustrated in FIG. 1, the hinge portion 4 includes the link 21, an arm 22, and first to third shafts 23, 24, and 25. The link 21 is an example of a “link component”, a “first member”, a “first component”, a “first connecting portion”, or a “first supporting portion”. The arm 22 is an example of an “arm component”, a “second member”, a “second component”, a “second connecting portion”, or a “second supporting portion”. In this embodiment, for example, only one hinge portion 4 is provided.

As illustrated in FIGS. 1, 2, and 8, the hinge portion 4 is provided inside the outline of the display screen 15. Specifically, the display screen 15 includes two ends 15a and 15b extending in the longitudinal direction of the arm 22. The arm 22 and the link 21 are closer to the inner side (e.g., center) of the display screen 15 than the two ends 15a and 15b.

As illustrated in FIGS. 1 to 5, a cut-out portion 26 is provided at the center portion of the projection 10 which is provided at the first end 9a of the first housing 6. The link 21 is provided in the cut-out portion 26 and is disposed at the first end 9a. In addition, the first shaft 23 is provided at the first end 9a. That is, the first shaft 23 is closer to the first end 9a than to the center of the first housing 6. The first shaft 23 is substantially parallel to the first surface 7a and extends along the first end 9a. The first shaft 23 is higher than the first surface 7a. The torque of the first shaft 23 is greater than that of the second shaft 24 or the third shaft 25.

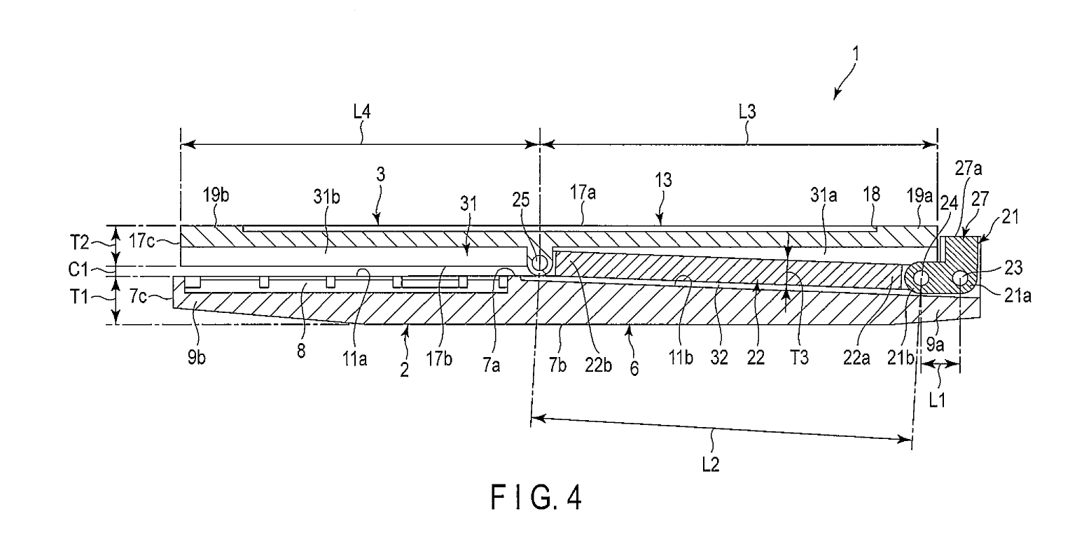

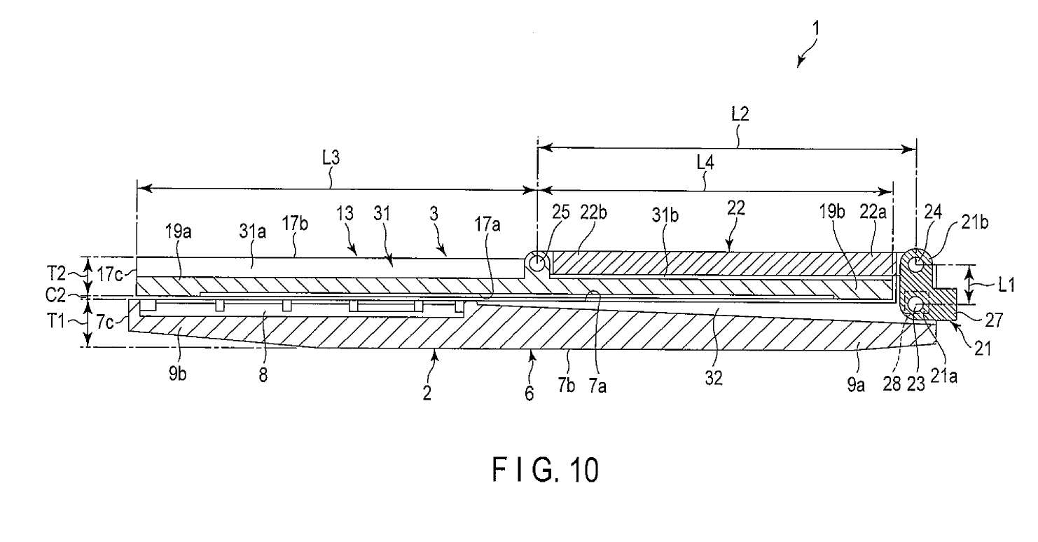

As illustrated in FIGS. 4 and 10, the link 21 includes a first portion 21a and a second portion 21b. The first portion 21a is connected to (i.e., supported by) the first shaft 23. That is, the first shaft 23 is disposed between the first end 9a of the first housing 6 and the first portion 21a of the link 21 and rotatably connects the first end 9a of the first housing 6 and the first portion 21a of the link 21.

The second portion 21b is opposite to the first portion 21a. The second portion 21b is an example of a “movable portion”, is rotated about the first shaft 23, and is movable between a first position (see FIG. 4) and a second position (see FIG. 10). As illustrated in FIG. 4, at the first position, the second portion 21b is adjacent to the first surface 7a of the first housing 6 and faces the first surface 7a. At the first position, the first portion 21a and the second portion 21b are arranged in a direction which is substantially parallel to the first surface 7a. The distances of the second portion 21b and the first portion 21a from the first surface 7a are substantially equal to each other.

As illustrated in FIG. 10, for example, the second position is rotated about 90 degrees from the first position. At the second position, the second portion 21b rises from the first position and is higher than the first position. The second position is further away from the first housing 6 than the first position. At the second position, the height of the second portion 21b is substantially equal to that of the second surface 17b of the second housing 13 in a third state (which will be described below). At the second position, the first portion 21a and the second portion 21b are arranged in a direction crossing (for example, a direction substantially perpendicular to) the first surface 7a.

As illustrated in FIG. 4, the first portion 21a of the link 21 includes a projection 27 (hereinafter, referred to as a second projection 27). The second projection 27 has substantially the same outward appearance as the projection 10 (hereinafter, referred to as the first projection 10) of the first housing 6. At the first position, the amount of protrusion of the second projection 27 is substantially equal to the amount of protrusion of the first projection 10. The second projection 27 is substantially continuous with the first projection 19. In this way, a series of projections is formed at the first end 9a of the first housing 6. The second projection 27 includes a plane 27a which is substantially flush with the plane 10a of the first projection 10.

A component (e.g., a functional component or an electronic component), such as a connector, may be mounted on the link 21. The link 21 may include a lock 28 (i.e., locking mechanism) for holding at least one of the first position and the second position.

As illustrated in FIGS. 4 and 10, the second shaft 24 is attached to the second portion 21b of the link 21. That is, the second shaft 24 is moved between the first position and the second position with the rotation of the link 21. The second shaft 24 is provided substantially in parallel to the first shaft 23. A distance L1 (i.e., distance between the centers of) between the second shaft 24 and the first shaft 23 is substantially equal to the thickness T2 of the second housing 13.

As illustrated in FIGS. 4 and 10, the third shaft 25 is attached to the second housing 13. The third shaft 25 is substantially parallel to the first shaft 23 and the second shaft 24. The third shaft 25 is attached substantially at the center of the second surface 17b of the second housing 13. The third shaft 25 is disposed substantially on the same plane as the second surface 17b of the second housing 13.

The length of the arm 22 is about half the length of the second housing 13 and the arm 22 extends between the second shaft 24 and the third shaft 25. The arm 22 includes a first portion 22a and a second portion 22b. The first portion 22a is connected to (i.e., supported by) the second shaft 24. The second portion 22b is connected to (i.e., supported by) the third shaft 25.

In other words, the second shaft 24 is disposed between the second portion 21b of the link 21 and the first portion 22a of the arm 22 and rotatably connects the second portion 21b of the link 21 and the first portion 22a of the arm 22. The third shaft 25 is disposed between the second portion 22b of the arm 22 and the second housing 13 and rotatably connects the second portion 22b of the arm 22 and the second housing 13.

A distance L2 (i.e., distance between the centers of) between the third shaft 25 and the second shaft 24 is shorter than a distance L3 between the third shaft 25 and the first end 19a of the second housing 13 and is greater than a distance L4 between the third shaft 25 and the second end 19b of the second housing 13.

The deviation of the third shaft 25 from the center of the second housing 13 is equal to about half the distance L1 between the first shaft 23 and the second shaft 24. In other words, the difference between the distance L3 between the third shaft 25 and the first end 19a of the second housing 13 and the distance L4 between the third shaft 25 and the second end 19b of the second housing 13 is substantially equal to the distance L1 between the first shaft 23 and the second shaft 24.

The electronic apparatus 1 can be deformed between the following first to fourth states (i.e., forms or positions). FIGS. 2 to 5 illustrate the first state (i.e., first form) of the electronic apparatus 1. The first state is a so-called tablet-used state (i.e., first use state). In the first state, the second housing 13 overlaps the first housing 6 substantially in parallel, with the display screen 15 facing upward.

That is, in the first state, the first surface 17a of the second housing 13 is disposed on the upper side and the second surface 17b of the second housing 13 is disposed on the lower side. The second surface 17b of the second housing 13 faces substantially the entire first housing 6 and faces the input portion 8 of the first housing 6. In the first state, the second housing 13 covers most of the first housing 6. The display screen 15 is disposed on the upper side and is exposed to the outside. The user can input information through the display screen 15.

As illustrated in FIG. 4, in the first state, the second portion 21b of the link 21 is at the first position. That is, the link 21 is laid and is close to the first housing 6. The second portion 21b of the link 21 faces the first housing 6.

The arm 22 is supported by the link 21 at the first position and is disposed between the first housing 6 and the second housing 13. That is, the first portion 22a of the arm 22 is close to the first housing 6 and faces the first housing 6. The second portion 22b of the arm 22 connected to the third shaft 25 is closer to the first housing 6 than the display screen 15 and faces the first housing 6. In this state, the first shaft 23, the second shaft 24, and the third shaft 25 are arranged on a substantially straight line.

The distance L3 between the third shaft 25 and the first end 19a of the second housing 13 is greater than the distance L2 between the third shaft 25 and the second shaft 24. Therefore, the second shaft 24 and the second portion 21b of the link 21 are covered with the first end 19a of the second housing 13 and are disposed between the second housing 13 and the first housing 6. In this way, most of the first housing 6 is covered with the second housing 13.

As illustrated in FIG. 4, the first end 19a of the second housing 13 is closer to the center of the first housing 6 than the first end 9a of the first housing 6. The second end 19b of the second housing 13 is closer to the center of the first housing 6 than the second end 9b of the first housing 6. That is, the second housing 13 is disposed inside the outline of the first housing in a plan view.

As illustrated in FIG. 5, in the first state, a clearance C1 between the first housing 6 and the second housing 13 is less than, for example, the thickness T3 of the arm 22. In addition, the clearance Cl is less than the thickness T1 of the first housing 6 and is less than the thickness T2 of the second housing 13.

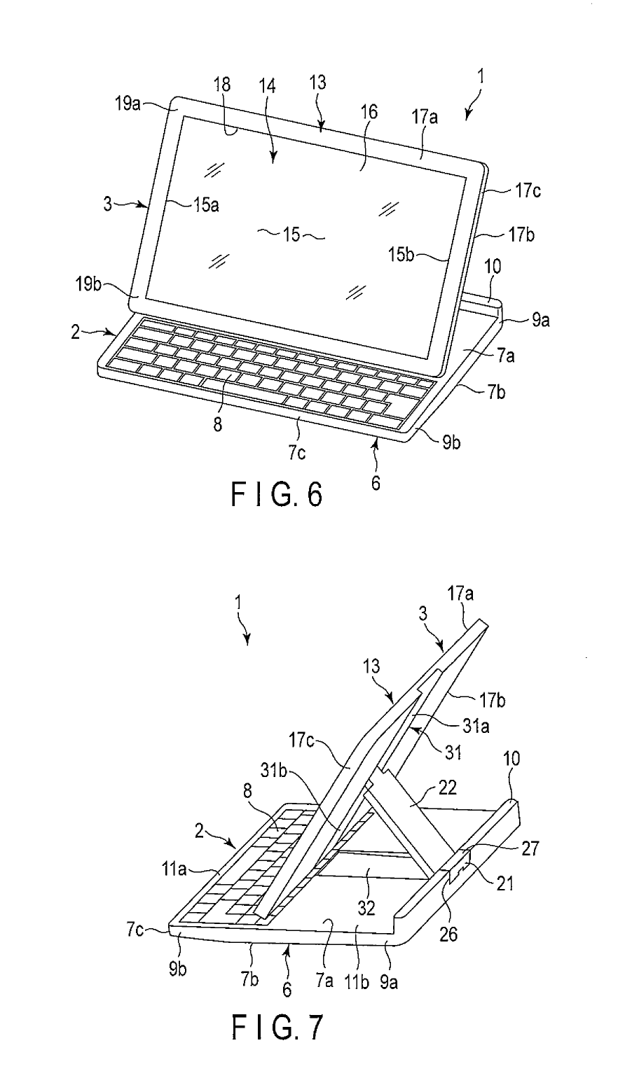

FIGS. 6 and 7 illustrate the second state (i.e., second form) of the electronic apparatus 1. The second state is a use state (i.e., second use state) in which the input portion 8 is exposed. In the second state, the second unit 3 is moved from the first state and the input portion 8 of the first unit 2 is exposed to the outside. Specifically, the arm 22 is rotated about the second shaft 24 with respect to the link 21 from the first state. In addition, the arm 22 is rotated about the third shaft 25 with respect to the second housing 13. With the rotation of the arm 22, the second housing 13 slides backward with respect to the first housing 6 and rises obliquely.

Then, the input portion 8 of the first housing 6 is exposed to the outside and can receive an input. The second housing 13 is disposed on the upper side of the second region 11b of the first housing 6 and is supported by the arm 22 which is inclined with respect to the first housing 6.

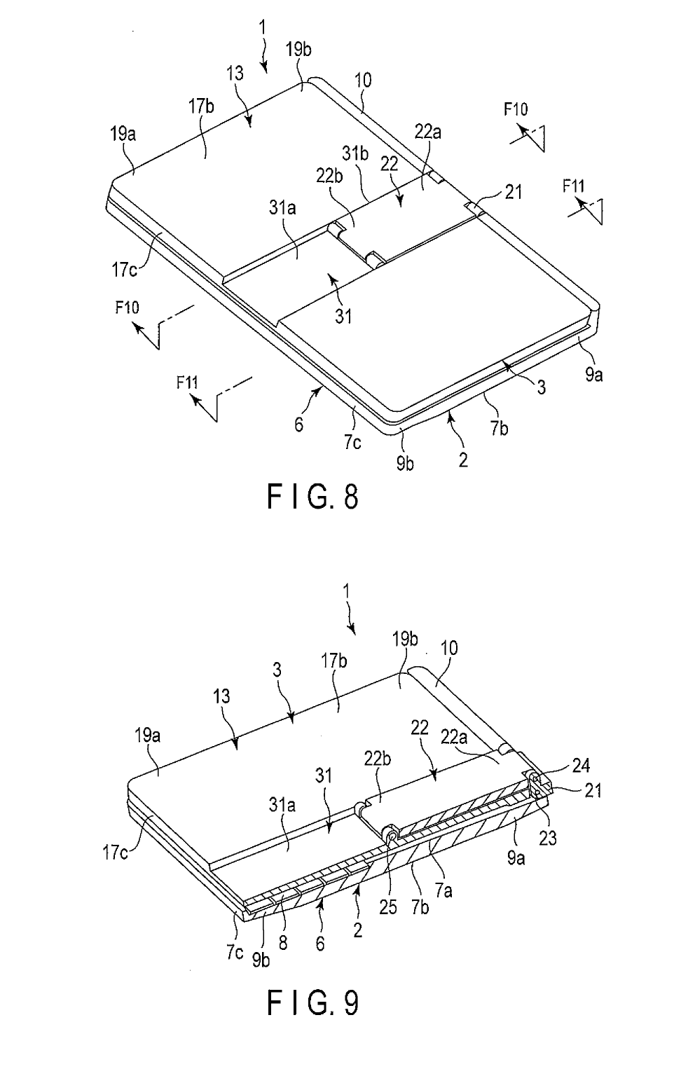

FIGS. 8 to 11 illustrate the third state (i.e., third form) of the electronic apparatus 1. The third state is a so-called screen protection state (i.e., a carried state or a non-used state). In the third state, the second housing 13 is inverted with respect to the first state such that the display screen 15 faces downward. The second housing 13 overlaps the first housing 6 substantially in parallel.

That is, in the third state, the second surface 17b of the second housing 13 is disposed on the upper side and the first surface 17a of the second housing 13 is disposed on the lower side. The first surface 17a of the second housing 13 faces substantially the entire first housing 6 and faces the input portion 8 of the first housing 6. In the third state, the second housing 13 covers most of the first housing 6. In other words, the entire display screen 15 is covered with the first surface 7a of the first housing 6. In this way, the display screen 15 is not exposed to the outside and is protected.

As illustrated in FIG. 10, in the third state, the second portion 21b of the link 21 is at the second position. That is, the second portion 21b of the link 21 is moved upward. The distance L1 between the second shaft 24 and the first shaft 23 is substantially equal to the thickness T2 of the second housing 13. Therefore, when the second portion 21b of the link 21 is moved from the first position to the second position, the second shaft 24 is moved a distance corresponding to the thickness of the second housing 13. In this way, the second shaft 24 is disposed above, for example, the display screen 15. In the third state, at least a portion of the second shaft 24 is disposed substantially on the same plane as the second surface 17b of the second housing 13.

The arm 22 is supported by the link 21 at the second position and a portion of the arm 22 overlaps the second unit 3 from the side opposite to the first housing 6. That is, the first portion 22a of the arm 22 connected to the second shaft 24 is disposed above the display screen 15. The arm 22 extends substantially in parallel to the second housing 13 at the position where it faces the second surface 17b of the second housing 13.

In this embodiment, the distance L4 between the third shaft 25 and the second end 19b of the second housing 13 is less than the distance L2 between the third shaft 25 and the second shaft 24. Therefore, the second end 19b of the second housing 13 does not overlap the link 21 and is aligned with the link 21 in the horizontal direction. Therefore, a clearance C2 between the second housing 13 and the first housing 6 can be reduced without being affected by the thickness of the link 21.

As illustrated in FIG. 10, in the third state, the first end 19a of the second housing 13 faces the second end 9b of the first housing 6. The second end 19b of the second housing 13 faces the first end 9a of the first housing 6. The first end 19a of the second housing 13 is closer to the center of the first housing 6 than the second end 9b of the first housing 6. The second end 19b of the second housing 13 is closer to the center of the first housing 6 than the first end 9a of the first housing 6. That is, the second housing 13 is disposed inside the outline of the first housing in a plan view.

As illustrated in FIG. 10, in the third state, the clearance C2 between the first housing 6 and the second housing 13 is less than, for example, the thickness T3 of the arm 22. The clearance C2 is less than the thickness T1 of the first housing 6 and is less than the thickness T2 of the second housing 13.

As illustrated in FIGS. 4 and 7 to 10, a first recess 31 (i.e., first groove) is provided on the second surface 17b of the second housing 13. The first recess 31 includes a first portion 31a and a second portion 31b. The first portion 31a extends between the third shaft 25 and the first end 19a of the second housing 13. The second portion 31b extends between the third shaft 25 and the second end 19b of the second housing 13. In other words, the first recess 31 extends between the first end 19a and the second end 19b of the second housing 13. The third shaft 25 is disposed between the first portion 31a and the second portion 31b. That is, the first portion 31a and the second portion 31b are separately provided on both sides of the third shaft 25.

The first recess 31 is provided at a position corresponding to the arm 22 and the link 21 and has substantially the same width as the arm 22 and the link 21. The first portion 31a receives the arm 22 and the second portion 21b of the link 21 in the first state. In the first state, at least a portion of each of the arm 22 and the second portion 21b of the link 21 is accommodated in the first portion 31a. The second portion 31b receives the arm 22 in the third state. At least a portion of the arm 22 is accommodated in the second portion 31b in the third state.

As illustrated in FIGS. 1, 4, and 7 to 10, a second recess 32 (second groove) is provided on the first surface 7a of the first housing 6. The second recess 32 is provided in the second region 11b of the first surface 7a. The second recess 32 extends between the first end 9a of the first housing 6 and the first region 11a. The second recess 32 is provided at a position corresponding to the arm 22 and the link 21 and has substantially the same width as the arm 22 and the link 21. In the first state, at least a portion of each of the arm 22 and the link 21 is accommodated in the second recess 32. In this way, portions of the arm 22 and the link 21 are accommodated between the first housing 6 and the second housing 13.

The entire arm 22 may be accommodated in the first recess 31. Instead of this structure, the entire arm 22 may be accommodated in the second recess 32. That is, only one of the first recess 32 and the first recess 31 may be provided.

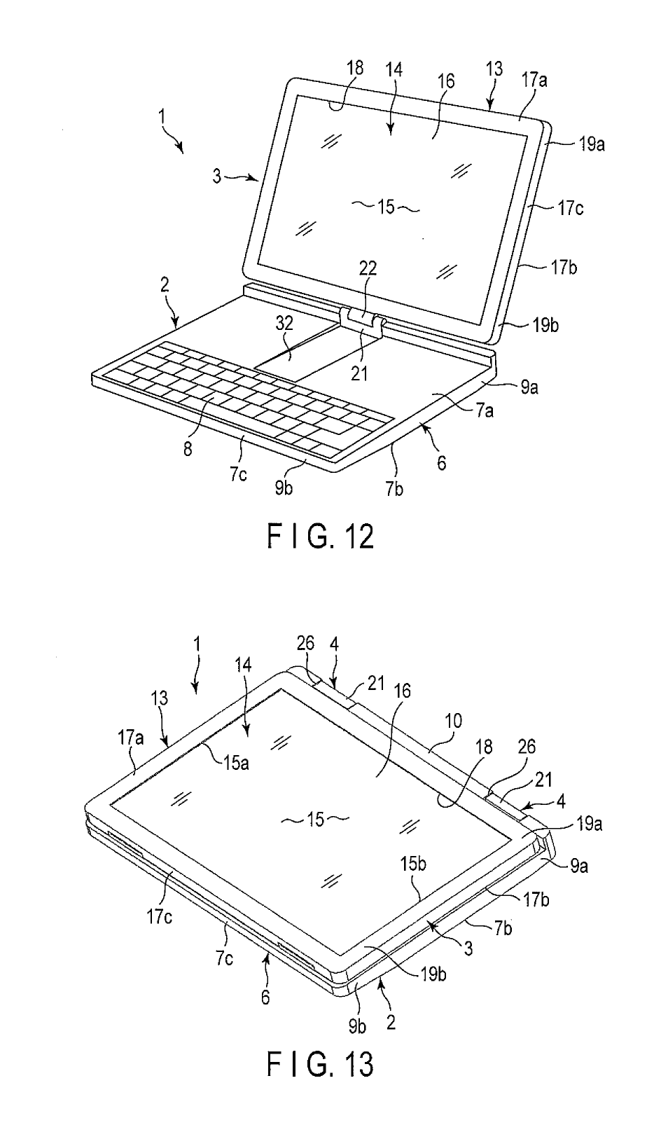

FIG. 12 illustrates the fourth state (i.e., fourth form) of the electronic apparatus 1. The fourth state is a use state (i.e., third use state) in which the second housing 13 is rotated to the rear side of the first housing 6 and the input portion 8 is exposed. In the fourth state, the link 21 rises from the second state and the second unit 3 is moved to the rear side of the link 21. In the fourth state, the electronic apparatus 1 can be used in the same position as a general notebook PC.

Next, the operation of the electronic apparatus 1 according to this embodiment will be described.

As illustrated in FIGS. 2 to 5, the electronic apparatus 1 can be changed to the first state by disposing the link 21 at the first position, laying the arm 22 down, and overlapping the second housing 13 with the first housing 6 with the display screen 15 facing upward. Then, the user can use the electronic apparatus 1 in a tablet state.

As illustrated in FIGS. 6 and 7, when the second housing 13 slides backward from the first state so as to rise obliquely, the input portion 8 (e.g., keyboard) is exposed and the electronic apparatus 1 can be changed to the second state. Then, the user can use the electronic apparatus 1 with the input portion 8 of the first unit 2.

As illustrated in FIGS. 8 to 11, the electronic apparatus 1 can be changed from the second state to the third state by rotating the link 21, raising the second portion 21b of the link 21 by a height corresponding to the thickness of the second housing 13, and overlapping the second housing 13 with the first housing 6 with the display screen 15 facing downward. Then, the display screen 15 is not exposed to the outside and the display screen 15 can be protected.

According to this structure, the thickness of the electronic apparatus can be reduced and the screen can be protected.

The electronic apparatus 1 according to this embodiment includes the link 21 and the arm 22. The link 21 is supported by the first housing 6 and a portion of the link 22 is movable between the first position and the second position which is further away from the first housing 6 than the first position. In the first state where the second surface 17b of the second housing 13 faces the first housing 6, the arm 22 is supported by the link 21 at the first position and is disposed between the second housing 13 and the first housing 6. In the third state where the first surface 17a of the second housing 13 faces the first housing 6, the arm 22 is supported by the link 21 at the second position and a portion of the arm 22 overlaps the second housing 13 from the side opposite to the first housing 6.

That is, in this embodiment, the height (i.e., position) of the second portion 21b of the link 21 supporting the arm 22 can be changed. Therefore, the arm 22 is disposed between the first housing 6 and the second housing 13 in the first state. In the third state, the arm 22 overlaps the second housing 13 from the side opposite to the first housing 6. Therefore, in the third state, since the arm 22 is not interposed between the first housing 6 and the display screen 15, the clearance C2 between the first housing 6 and the second housing 13 can be reduced. In this way, a reduction in the thickness of the electronic apparatus and the protection of the screen can be simultaneously achieved.

In this embodiment, the second unit 3 is moved to change the electronic apparatus 1 from the first state to the second state where the input portion 8 of the first unit 2 is exposed. Therefore, the input portion 8 of the first unit 2 can be used and the electronic apparatus 1 can be used with the display screen 15 of the second unit 3 rising obliquely. According to this structure, the usability of the electronic apparatus 1 can be improved.

In this embodiment, the first recess 31 including the first portion 31a in which at least a portion of the arm 22 is accommodated in the first state and the second portion 31b in which at least a portion of the arm 22 is accommodated in the third state is provided in the second surface 17b of the second unit 3. In this structure, in the first state and the third state, the arm 22 is accommodated in the first recess 31. Therefore, the thickness of the electronic apparatus 1 can be further reduced.

In this embodiment, the first portion 31a of the first recess 31 extends between the third shaft 25 and the first end 19a of the second unit 3. The second portion 31b of the first recess 31 extends between the third shaft 25 and the second end 19b of the second unit 3. According to this structure, the arm 22 is accommodated in the first recess 31 over the almost entire length between the first end 19a of the second housing 13 and the second end 19b. In this way, the thickness of the electronic apparatus 1 can be further reduced.

In this embodiment, the distance L2 between the centers of the third shaft 25 and the second shaft 24 is less than the distance L3 between the third shaft 25 and the first end 19a of the second housing 13 and is greater than the distance L4 between the third shaft 25 and the second end 19b of the second housing 13. In this way, in both the first state and the third state, the second unit 3 is in the first unit 2 in a plan view. Therefore, the first unit 2 can stably support the second unit 3.

In this embodiment, the first unit 2 includes the second recess 32 in which at least a portion of the arm 22 is accommodated in the first state. According to this structure, the thickness of the electronic apparatus 1 can be further reduced.

In this embodiment, the display screen 15 includes two ends 15a and 15b extending in the longitudinal direction of the arm 22. The link 21 and the arm 22 are closer to the center of the display screen 15 than the two ends 15a and 15b of the display screen 15. According to this structure, the size of the second housing 13 can be reduced according to the size of the display device 14. As a result, the size of the electronic apparatus 1 can be reduced.

In this embodiment, the first end 19a of the second unit 3 faces the first end 9a of the first unit 2 in the first state and faces the second end 9b of the first unit 2 in the third state. The second end 19b of the second unit 3 faces the second end 9b of the first unit 2 in the first state and faces the first end 9a of the first unit 2 in the third state. According to this structure, in the first state and the third state, the first end 19a and the second end 19b of the second unit 3 face the first unit 2 and can be supported by the first unit 2. Therefore, the stability and usability of the electronic apparatus 1 can be improved and the screen can be protected.

### SECOND EMBODIMENT

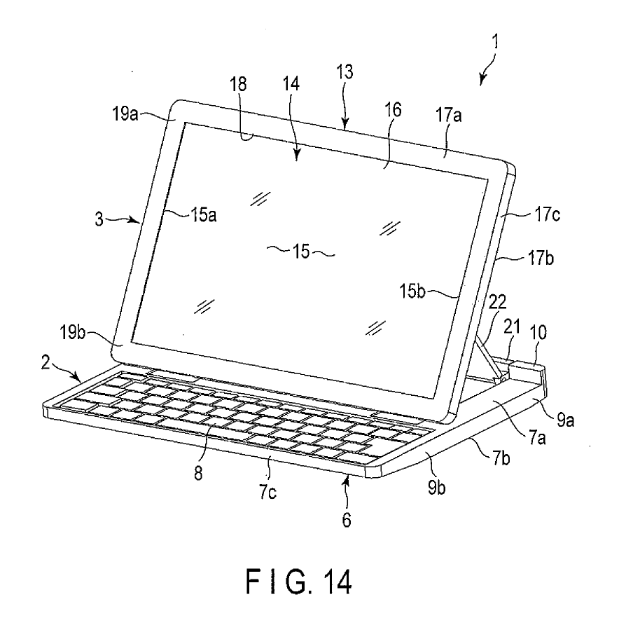

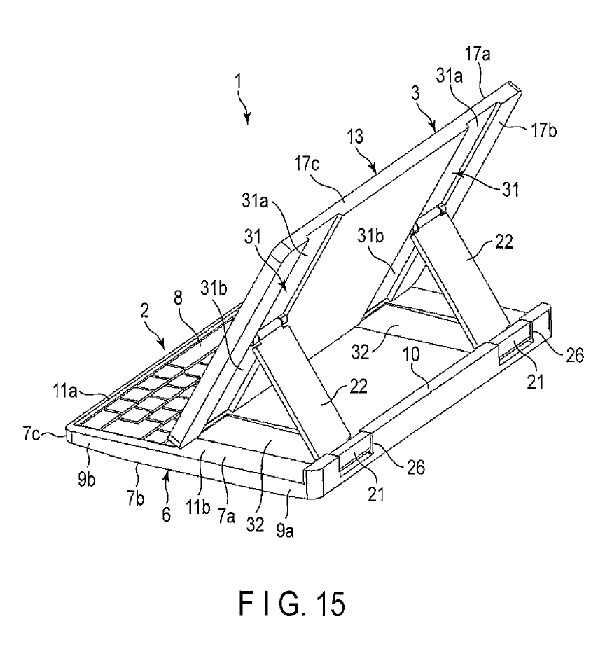

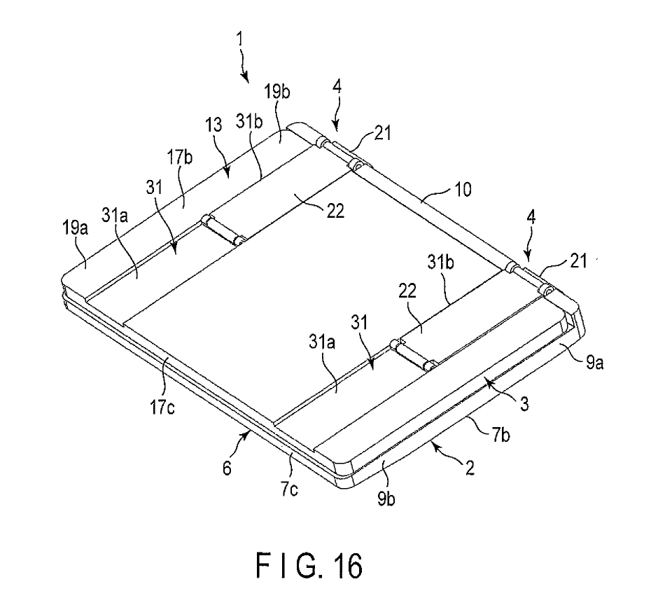

Next, an electronic apparatus 1 according to a second embodiment will be described with reference to FIGS. 13 to 16. In the second embodiment, components having the same or similar functions as those in the first embodiment are denoted by the same reference numerals and the description thereof will not be repeated. Structures other than the following structures are the same as those in the first embodiment.

The electronic apparatus 1 according to this embodiment includes two hinge portions 4. The structure of each of the hinge portions 4 is the same as that in the first embodiment. The two hinge portions 4 are closer to the center of a display screen 15 than two ends 15a and 15b of the display screen 15.

According to this structure, similarly to the first embodiment, the thickness of the electronic apparatus can be reduced and the screen can be protected.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

For example, in the above-described embodiments, the width of the first recess 31 and the second recess 32 is substantially equal to the width of the arm 22, but the embodiments are not limited thereto. For example, the first recess 31 and the second recess 32 may be provided as follows: the first recess 31 and the second recess 32 are provided in the almost entire surface of each of the second housing 13 and the first housing 6 and ribs are provided at the edges of the second housing 13 and the first housing 6.

In the above-described embodiment, the second housing 13 is disposed inside the first housing 6 in the first state and the third state, but the embodiments are not limited thereto. The second housing 13 may protrude from the first housing 6. The depth and shape of the first recess 31 and the second recess 32 are not limited to those in the above-described embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first unit comprising an input receiving portion;
a second unit comprising a first surface and a second surface, the first surface comprising a display comprising a touch sensor, the second surface opposite the first surface;
a first shaft at an end of the first unit;
a first member rotatable about the first shaft, the first member comprising a movable portion movable between a first position where the movable portion faces the first unit and a second position where the movable portion is farther from the first unit than when in the first position;
a second shaft in the movable portion;
a third shaft in the second unit; and
a second member comprising a first portion connected to the second shaft and a second portion connected to the third shaft,
wherein, in a first state where the second surface of the second unit faces the input receiving portion, the second member is configured to be supported by the first member in the first position, the second member comprising a portion between the second unit and the first unit,
in a second state where the second unit is moved from the first state and the input receiving portion is exposed, the second member is configured to be inclined with respect to the first unit and support the second unit, and
in a third state where the first surface of the second unit faces the input receiving portion, the second member is configured to be supported by the first member in the second position, the second unit comprising a portion between the second member and the first unit.

2. The electronic apparatus of claim 1,
wherein the second surface of the second unit comprises a first recess, the first recess comprising a first recess portion and a second recess portion, the first recess portion configured to receive at least a portion of the second member in the first state, the second recess portion configured to receive at least a portion of the second member in the third state.

3. The electronic apparatus of claim 2,
wherein the first recess portion and the second recess portion are separately located on either side of the third shaft.

4. The electronic apparatus of claim 3,
wherein the second unit comprises a first end and a second end, the first end configured to face the first member in the first state, the second end opposite the first end,
the first recess portion is configured to extend between the third shaft and the first end, and
the second recess portion is configured to extend between the third shaft and the second end.

5. The electronic apparatus of claim 4,
wherein a first distance between centers of the third shaft and the second shaft is configured to be less than a second distance between the third shaft and the first end, and the first distance is configured to be greater than a third distance between the third shaft and the second end, and
the second unit is configured to be inside an outline of the first unit in the first state and the third state.

6. The electronic apparatus of claim 1,
wherein, the first unit comprises a second recess configured to receive at least a portion of the second member in the first state.

7. The electronic apparatus of claim 1,
wherein, in the third state, the second shaft comprises a portion substantially on a same plane as the second surface of the second unit.

8. The electronic apparatus of claim 7,
wherein, the first unit comprises a second recess configured to receive at least a portion of the second member in the first state.

9. The electronic apparatus of claim 1,
wherein the display comprises two ends extending in a longitudinal direction relative to the second member, and
the second member is configured closer to a central part of the display than the two ends of the display.

10. The electronic apparatus of claim 1,
wherein the first unit comprises a first end and a second end, the first end comprising the third shaft, the second end opposite the first end, and
the second unit comprises a first end and a second end, the first end of the second unit configured to face the first end of the first unit in the first state and to face the second end of the first unit in the third state, and the second end of the second unit configured to face the second end of the first unit in the first state and to face the first end of the first unit in the third state.

11. An electronic apparatus comprising:
a first housing;
a second housing comprising a first surface and a second surface, the second surface opposite the first surface;
a first member supported by the first housing, the first member comprising a portion movable between a first position and a second position, the second position farther from the first housing than the first position; and
a second member connecting the first member and the second housing,
wherein, the second member is configured to be supported by the first member in the first position, the second member comprises a portion between the second housing and the first housing in a first state where the second surface of the second housing faces the first housing, and
the second member is configured to be supported by the first member in the second position, the portion of the second member faces the second housing from a side opposite to the first housing in a second state where the first surface of the second housing faces the first housing.
